(19) United States
(12) Patent Application Publication
(10) Pub. No.: US 2023/0030749 A1
(43) Pub. Date: Feb. 2, 2023

(54) HYBRID FENCED SUBSTRATE FOR TRANSVERSELY-EXCITED FILM BULK ACOUSTIC RESONATOR FRONTSIDE MEMBRANE RELEASE

(71) Applicant: Resonant Inc., Austin, TX (US)

(72) Inventors: Chris O'Brien, San Diego, CA (US); Albert Cardona, Santa Barbara, CA (US)

(21) Appl. No.: 17/726,467

(22) Filed: Apr. 21, 2022

Related U.S. Application Data
(60) Provisional application No. 63/228,347, filed on Aug. 2, 2021.

(51) Int. Cl. H03H 9/02; H03H 3/02; H03H 9/15; H03H 9/54

(52) U.S. Cl. CPC H03H 9/02228; H03H 3/02; H03H 9/15; H03H 9/54; H03H 9/02015

(57) ABSTRACT

Acoustic resonator devices and methods are disclosed. An acoustic resonator device includes a substrate having a front surface and a cavity. A depth of the cavity is defined by a buried oxide layer comprising etch-stop material and a perimeter of the cavity is defined by lateral fences comprising etch-stop material. A back surface of a single-crystal piezoelectric plate is attached to the front surface of the substrate except for a portion of the piezoelectric plate that forms a diaphragm that spans the cavity. An interdigital transducer (IDT) is formed on the front surface of the single-crystal piezoelectric plate such that interleaved fingers of the IDT are disposed on the diaphragm.

### RELATED APPLICATION INFORMATION

This patent claims priority from the provisional patent application No. 63/228,347, filed Aug. 2, 2021, entitled HYBRID FENCE FOR XBAR FRONTSIDE MEMBRANE RELEASE.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to radio frequency filters using acoustic wave resonators, and specifically to filters for use in communications equipment.

### Description of the Related Art

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a passband or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5^{th} generation mobile networks is defined in the 5G NR (new radio) standard. The 5G NR standard defines several new communications bands. Two of these new communications bands are n77, which uses the frequency range from 3300 MHz to 4200 MHz, and n79, which uses the frequency range from 4400 MHz to 5000 MHz. Both band n77 and band n79 use time-division duplexing (TDD), such that a communications device operating in band n77 and/or band n79 use the same frequencies for both uplink and downlink transmissions. Bandpass filters for bands n77and n79 must be capable of handling the transmit power of the communications device. The 5G NR standard also defines millimeter wave communication bands with frequencies between 24.25 GHz and 40 GHz.

The Transversely-Excited Film Bulk Acoustic Resonator (XBAR) is an acoustic resonator structure for use in microwave filters. The XBAR is described in patent U.S. Pat. No. 10,491,291, titled TRANSVERSELY EXCITED FILM BULK ACOUSTIC RESONATOR. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz.

### DESCRIPTION OF THE DRAWINGS

FIG. 1 includes a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3A is an alternative schematic cross-sectional view of an XBAR.

FIG. 3B is another alternative schematic cross-sectional view of XBARs.

FIG. 4 is a flow chart of a conventional process for fabricating an XBAR.

FIG. 5A, FIG. 5B, and FIG. 5C (collectively “FIG. 5”) are a flow chart of another process for fabricating an XBAR using lateral fences.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

The Transversely-Excited Film Bulk Acoustic Resonator (XBAR) is a new resonator structure for use in microwave filters. The XBAR is described in patent U.S. Pat. No. 10,491,291, titled TRANSVERSELY EXCITED FILM BULK ACOUSTIC RESONATOR, which is incorporated herein by reference in its totality. An XBAR resonator comprises a conductor pattern having an interdigital transducer (IDT) formed on a thin floating layer or diaphragm of a piezoelectric material. The IDT has two busbars which are each attached to a set of fingers and the two sets of fingers are interleaved on the diaphragm over a cavity formed in a substrate upon which the resonator is mounted. The diaphragm spans the cavity and may include front-side and/or back-side dielectric layers. A microwave signal applied to the IDT excites a shear primary acoustic wave in the piezoelectric diaphragm, such that the acoustic energy flows substantially normal to the surfaces of the layer, which is orthogonal or transverse to the direction of the electric field generated by the IDT. XBAR resonators provide very high electromechanical coupling and high frequency capability.

A piezoelectric membrane may be a part of a plate of single-crystal piezoelectric material that spans a cavity in the substrate. A piezoelectric diaphragm may be the membrane and may include the front-side and/or back-side dielectric layers. An XBAR resonator may be such a diaphragm or membrane with an interdigital transducer (IDT) formed on a diaphragm or membrane.

Currently XBAR fabrication processes may be divided into two broad categories known as “the front-side etch option” or a frontside membrane release (FSMR) and the “backside etch option” or a backside membrane release (BSMR). With the front-side etch option, the piezoelectric plate is attached to a substrate and the diaphragm portion of the piezoelectric plate floats over a cavity (the “swimming pool”) formed by etching the substrate or a sacrificial material using an etchant introduced through holes in the piezoelectric plate. With the backside etch option, the piezoelectric plate is attached to a substrate and the diaphragm portion of the piezoelectric plate floats over a void etched through the substrate from the back side (i.e. the side opposite the piezoelectric plate).

Described herein are devices having and methods of forming XBARs with a hybrid fences patterned substrate for frontside membrane release (FSMR) of the plate, such as after an IDT has been formed. The hybrid fences may use lateral fences to bound the horizontal width and length of the cavities; and may use an implanted buried oxide layer to bound the vertical depth of the cavities when the cavities are etched under the membrane through holes in the membrane. These embodiments include methods that form sacrificial silicon tubs in piezoelectric on insulator (POI) wafers or substrates within the hybrid fences for XBAR FSMR without a silicon deposition stage in the substrate of sacrificial material in the cavity location. These embodiments solve problems by providing POI substrates which are preferred for XBAR manufacturing because they will release the piezoelectric plate membrane by an etch of a sacrificial material, such as a material of poly silicon.

Many prior approaches to solve this problem suffer from using a substrate preparation for silicon based sacrificial materials that is limited in membrane density and cavity depth because of bonding and silicon deposition steps. Two primary challenges are encountered preparing substrates with an etch cavity then sacrificial fill approach. First, a chemical mechanical polish (CMP) processes to prepare for bonding will consume the different material types at different rates, causing dishing in these regions, which can compromise bond success and increase variation of piezo-electric thickness in sacrificial areas, which is critical for device operation. Second, bonding the piezo-electrical layer to unlike materials can limit the selection of sacrificial materials or total density of patterned features.

The embodiments herein overcome these challenges by forming the etch stop layers within a layer of existing sacrificial silicon, instead of using the bonding and silicon deposition steps, or etch cavity then sacrificial fill approach. In the embodiments herein, different material is limited to the to the boundaries of cavities rather than the area. Thus, CMP conditions can be optimized for LN plate thickness over the consistent Si layer material, which will form the critical final structure without as much impact from layout specific effects. The embodiments herein use hybrid fences patterned substrate for FSMR of the plate to bypasses both the above bonding and silicon deposition steps to facilitate arbitrary depth and pattern density of the sacrificial material and/or cavity.

### Description of Apparatus

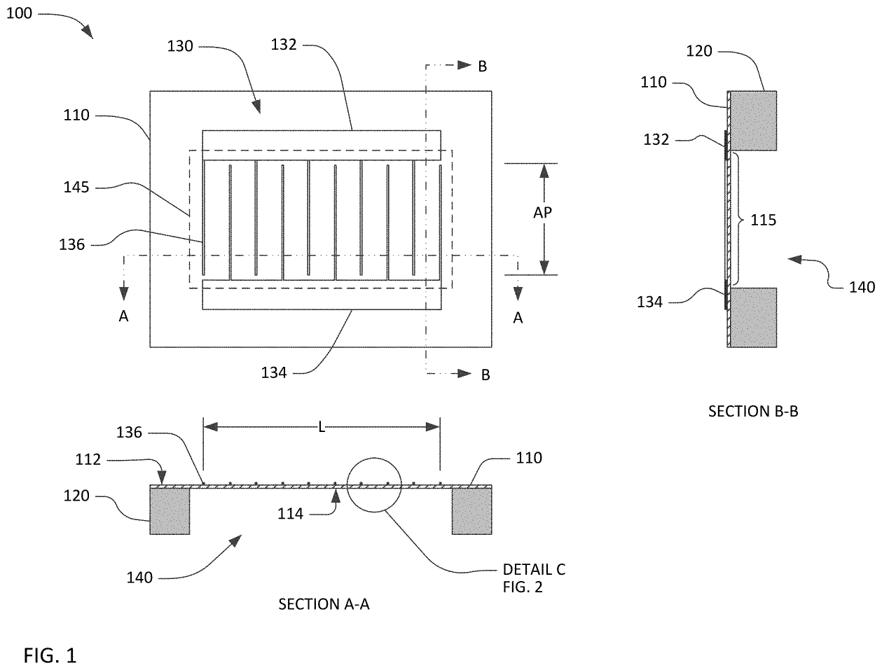

FIG. 1 shows an XBAR 100 made up of a thin film conductor pattern formed on a surface of a piezoelectric plate 110 having parallel front and back surfaces 112, 114, respectively. The piezoelectric plate 110 is a thin single-crystal layer of a piezoelectric material such as lithium niobate (LN), lithium tantalate (LT), lanthanum gallium silicate, gallium nitride, or aluminum nitride. The piezoelectric plate is cut such that the orientation of the X, Y, and Z crystalline axes with respect to the front and back surfaces is known and consistent. In the examples presented, the piezoelectric plates may be Z-cut, which is to say the Z axis is normal to the surfaces. However, XBARs may be fabricated on piezoelectric plates with other crystallographic orientations.

The back surface 114 of the piezoelectric plate 110 is attached to a substrate 120 that provides mechanical support to the piezoelectric plate 110. The substrate 120 may be, for example, silicon, sapphire, quartz, or some other material. The substrate may have layers of silicon thermal oxide (TOX), SiO2, Diamond, SiOC, Si3N4, Tungsten (W) and crystalline silicon. The back surface 114 of the piezoelectric plate 110 or a diaphragm 115 including the plate may be bonded to the substrate 120 using a wafer bonding process, or grown on the substrate 120, or attached to the substrate in some other manner. The piezoelectric plate may be attached directly to the substrate or may be attached to the substrate via one or more intermediate material layers, such as a bonding oxide (BOX) layer that may be SiO2.

The substrate 120 provides mechanical support to the piezoelectric plate 110. The substrate 120 may be, for example, silicon, sapphire, quartz, or some other material or combination of materials. The back surface 114 of the piezoelectric plate 110 may be bonded to the substrate 120 using a wafer bonding process. Alternatively, the piezoelectric plate 110 may be grown on the substrate 120 or attached to the substrate in some other manner. The piezoelectric plate 110 may be attached directly to the substrate or may be attached to the substrate 120 via one or more intermediate material layers.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. The excited primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

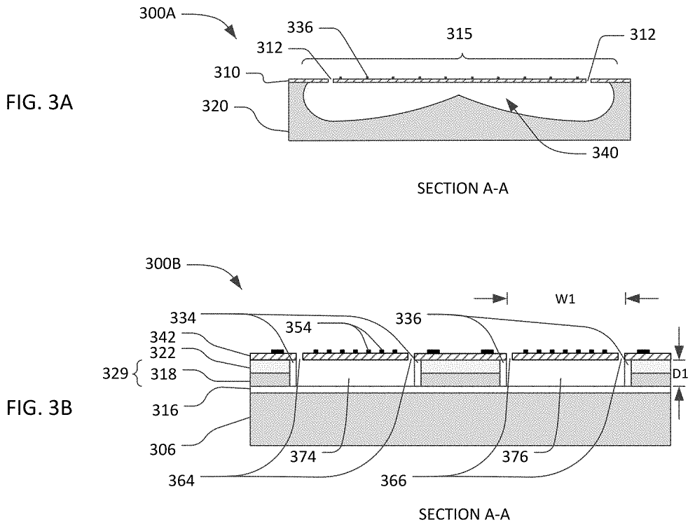

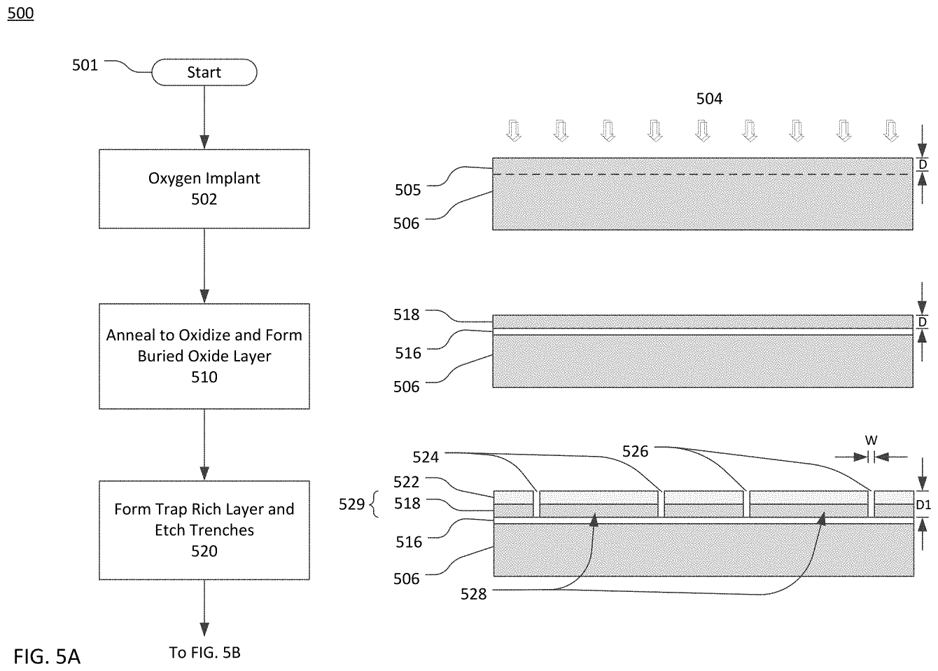

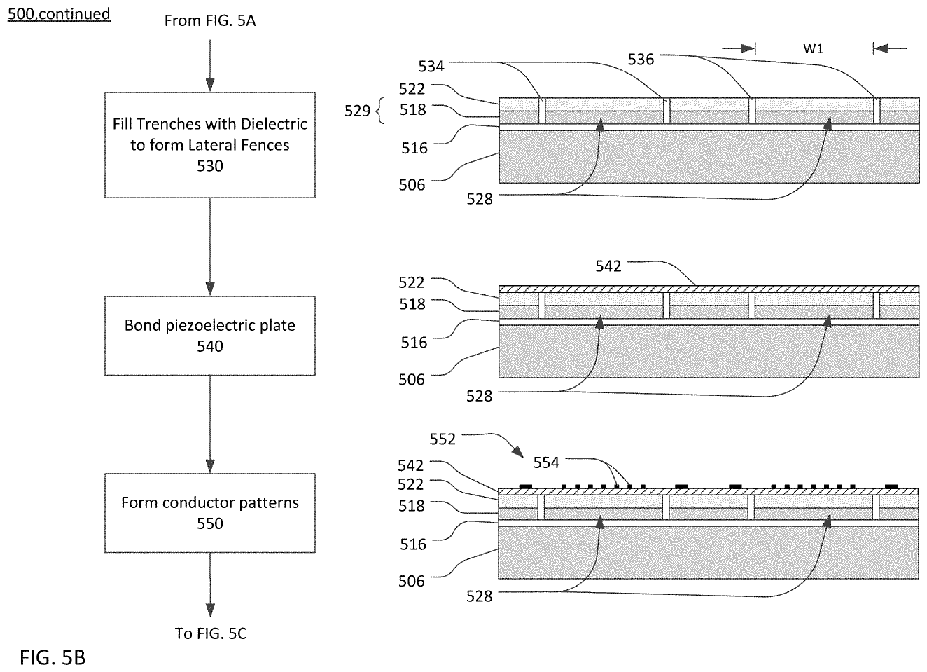

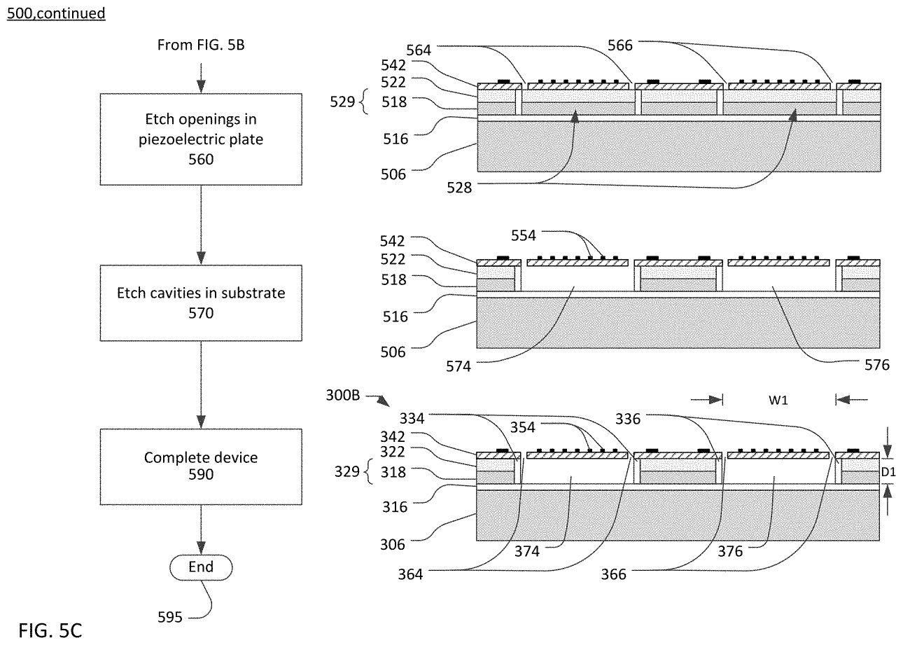

A cavity 140 is formed in the substrate 120 such that a portion 115 of the piezoelectric plate 110 containing the IDT 130 is suspended over the cavity 140 without contacting the substrate 120. “Cavity” has its conventional meaning of “an empty space within a solid body.” The cavity 140 may be a hole completely through the substrate 120 (as shown in Section A-A and Section B-B) or a recess in the substrate 120 (as shown subsequently in FIGS. 3A-3B and 5C-5C). The cavity 140 may be formed, for example, by selective etching of the substrate 120 before or after the piezoelectric plate 110 and the substrate 120 are attached.

The IDT 130 is positioned on the piezoelectric plate 110 such that at least the fingers of the IDT 130 are disposed on the portion 115 of the piezoelectric plate that spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

The portion 115 of the piezoelectric plate suspended over the cavity 140 will be referred to herein as the “diaphragm” 115 (for lack of a better term) due to its physical resemblance to the diaphragm of a microphone. The diaphragm 115 may be continuously and seamlessly connected to the rest of the piezoelectric plate 110 around all, or nearly all, of perimeter 145 of the cavity 140. In this context, “contiguous” means “continuously connected without any intervening item”. The IDT 130 is positioned on the piezoelectric plate 110 such that at least the fingers 136 of the IDT 130 are disposed on the diaphragm 115 of the piezoelectric plate that spans, or is suspended over, the cavity 140.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds, possibly thousands, of parallel fingers in the IDT 110. Similarly, the thickness of the fingers in the cross-sectional views is greatly exaggerated.

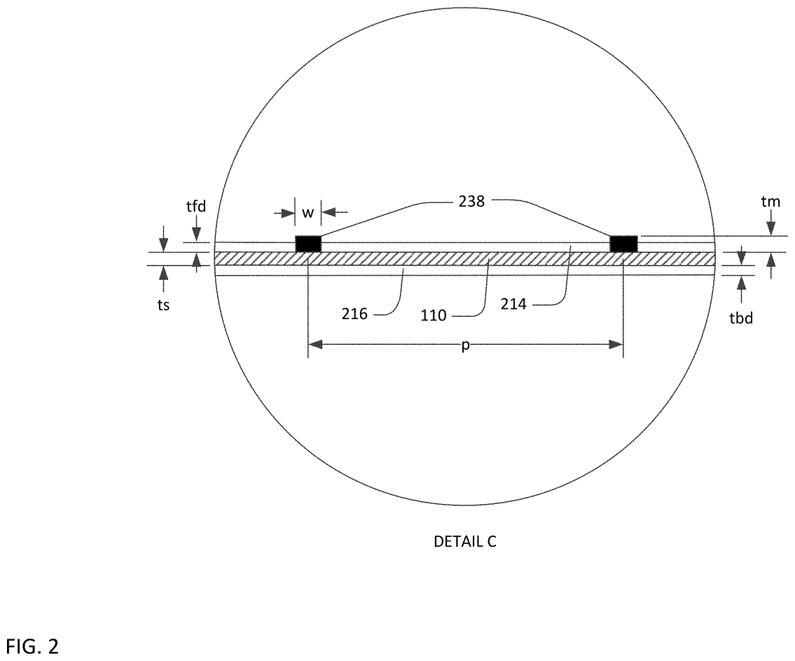

FIG. 2 shows a detailed schematic cross-sectional view (detail C) of the XBAR 100 of FIG. 1. The cross-sectional view may be a portion of the XBAR 100 that includes fingers of the IDT. The piezoelectric plate 110 is a single-crystal layer of piezoelectrical material having a thickness ts. ts may be, for example, 100 nm to 1500 nm. When used in filters for LTE™ bands from 3.4 GHZ to 6 GHz (e.g. bands n77, n79), the thickness ts may be, for example, 200 nm to 1000 nm.

A front-side dielectric layer 214 may optionally be formed on the front side of the piezoelectric plate 110. The “front side” of the XBAR is, by definition, the surface facing away from the substrate. The front-side dielectric layer 214 has a thickness tfd. The front-side dielectric layer 214 is formed between the IDT fingers 238. Although not shown in FIG. 2, the front side dielectric layer 214 may also be deposited over the IDT fingers 238. A back-side dielectric layer 216 may optionally be formed on the back side of the piezoelectric plate 110. The back-side dielectric layer 216 has a thickness tbd. The front-side and back-side dielectric layers 214, 216 may be a non-piezoelectric dielectric material, such as silicon dioxide or silicon nitride. tfd and tbd may be, for example, 0 to 500 nm. tfd and tbd are typically less than the thickness ts of the piezoelectric plate. tfd and tbd are not necessarily equal, and the front-side and back-side dielectric layers 214, 216 are not necessarily the same material. Either or both of the front-side and back-side dielectric layers 214, 216 may be formed of multiple layers of two or more materials.

The front side dielectric layer 214 may be formed over the IDTs of some (e.g., selected ones) of the XBAR devices in a filter. The front side dielectric 214 may be formed between and cover the IDT finger of some XBAR devices but not be formed on other XBAR devices. For example, a front side frequency-setting dielectric layer may be formed over the IDTs of shunt resonators to lower the resonance frequencies of the shunt resonators with respect to the resonance frequencies of series resonators, which have thinner or no front side dielectric. Some filters may include two or more different thicknesses of front side dielectric over various resonators. The resonance frequency of the resonators can be set thus “tuning” the resonator, at least in part, by selecting a thicknesses of the front side dielectric layer.

Further, a passivation layer may be formed over the total surface of the XBAR device 100 except for contact pads where electric connections are made to circuity external to the XBAR device. The passivation layer is a thin dielectric layer intended to seal and protect the surfaces of the XBAR device while the XBAR device is incorporated into a package. The front side dielectric layer and/or the passivation layer may be, SiO₂, Si₃N₄, Al₂O₃, some other dielectric material, or a combination of these materials.

The thickness of the passivation layer may be selected to protect the piezoelectric plate and the metal electrodes from water and chemical corrosion, particularly for power durability purposes. It may range from 10 to 100 nm. The passivation material may consist of one or more oxide and/or nitride coatings such as SiO2 and Si3N4 material.

The IDT fingers 238 may be one or more layers of aluminum or a substantially aluminum alloy, copper or a substantially copper alloy, beryllium, tungsten, molybdenum, gold, or some other conductive material. Thin (relative to the total thickness of the conductors) layers of other metals, such as chromium or titanium, may be formed under and/or over the fingers to improve adhesion between the fingers and the piezoelectric plate 110 and/or to passivate or encapsulate the fingers. The busbars (132, 134 in FIG. 1) of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers. The IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e. the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness is of the piezoelectric slab 110. The width of the IDT fingers in an XBAR is not constrained to one-fourth of the acoustic wavelength at resonance. For example, the width w of XBAR IDT fingers may be 500 nm or greater, such that the IDT can be fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

FIGS. 3A and FIG. 3B show alternative schematic cross-sectional views of resonator devices 300A and 300B along the section plane A-A defined in FIG. 1. In FIG. 3A, a piezoelectric plate 310 is attached to a substrate 320. A portion of the piezoelectric plate 310 forms a diaphragm 315 spanning a cavity 340 in the substrate. The cavity 340 does not fully penetrate the substrate 320. Fingers, such as finger 336, of an IDT are disposed on the diaphragm 315. The cavity 340 may be formed by etching the substrate 320 with a selective etchant that reaches the substrate through one or more openings 312 provided in the piezoelectric plate 310.

FIG. 3A illustrates problems that occur when the cavity is formed by etching the substrate 320 with a selective etchant that reaches the substrate through the openings 312 in the piezoelectric plate 310. The process used to form the cavity 340 will introduce a liquid or gaseous etchant via the holes 312. This etchant will etch isotropically, causing the cavity to expand in all directions from the holes 312. The resulting cavity will effectively increase the area of the diaphragm 315 beyond the area occupied by the IDT. Resistive and acoustic losses in the IDT generate heat in the diaphragm. Enlarging the diaphragm area beyond the area of the IDT increases the difficulty of removing the heat from the diaphragm. Further, the bottom of the cavity 340 will not be parallel to the piezoelectric plate 310. The deepest portions of the cavity will be proximate the holes 312 and the minimum depth of the cavity will occur near the center of the diaphragm 315.

The shape of the cavity in FIG. 3A is an artistic rendition of the potential problems with etching the cavity 340 with an etchant introduced through holes in the piezoelectric plate 310. The illustrated shape of the cavity is not based on simulation or measurement of an actual etching process.

In FIG. 3B, device 300B is shown with two resonators having cavities 374 and 376 formed with a hybrid fences patterned substrate for frontside membrane release (FSMR) of their piezoelectric plate membranes. The hybrid fences use lateral fences to bound the horizontal width and length of the cavities; and use an implanted buried oxide layer to bound the vertical depth of the cavities when the cavities are etched under the membrane through holes 364 and 366 in the membrane.

For device 300B a piezoelectric plate 342 is attached to a substrate 306, such as to trap rich layer 322 formed on device layer 318 in device portion 329 of the substrate. The trap rich layer 322 may be disposed between and in contact with the back surface of the piezoelectric plate 342 and the front surface of the substrate device layer 318. The trap rich layer 322 may be further described by layer 522 of FIG. 5A-C. In some cases, a bonding oxide layer is between the trap-rich layer and the piezoelectric plate. Portions of the piezoelectric plate 342 forms diaphragm (e.g., see diaphragm 315) spanning cavities 374 and 376 in the substrate. The cavities 374 and 376 do not fully penetrate the substrate 306. Fingers, such as finger 354, of an IDT are disposed on the diaphragms. The cavities 374 and 376 have been formed by etching the device portion 329 with a selective etchant that reaches the device portion 329 through one or more openings 364 and 366 in the piezoelectric plate 342. The lateral extent of the cavities 374 and 376 is defined by a lateral fences 334 and 336, where “lateral” is defined as any direction parallel the surfaces of the piezoelectric plate 342. Each of lateral fences 334 and 336 may be a vertical ‘fence’ feature formed by an Si etch and deposition of SiO2, silicon nitride, aluminum oxide, oxynitride or another etch stop material with respect to the substrate or device portion 329. While the lateral fences 334 and 336 are shown in cross-section with lateral width W1 in FIG. 3B, it should be understood that the lateral fences 334 and 336 are each a continuous closed band of etch-stop material that surrounds a cavity 374 and 376 such that the lateral fences also defines the size of each cavity 374 and 376 in the direction normal to the plane of the drawing. Each cavity extends from the back surface of the piezoelectric plate 342 though the device portion 329 to the buried oxide layer 316.

The vertical (i.e. the dimension normal to the surface of the piezoelectric plate 342) extent or depth D1 of the cavities 374 and 376 is defined by a vertical buried oxide layer 316. The buried oxide layer 316 may be a horizontal layer feature formed by oxide implantation and annealing to form an SiO2 or other etch stop material with respect to the substrate. The buried oxide layer 316 may be or include a layer of annealed implanted oxygen and silicon substrate material. The buried oxide layer 316 may not be a laminate or deposited layer; but may be formed by oxygen implantation an annealing to form a layer that is “buried” at depth D within the substrate. The vertical buried oxide 316 may be a horizontal ‘box’ feature, which can be formed through separation by implantation of oxygen (SIMOX) or wafer bonding. In this case, the cavities 374 and 376 have a rectangular, or nearly rectangular, cross section. In this patent, the term “vertical” encompasses a direction perpendicular to the surface of the substrate or piezoelectric plate.

The lateral fences 334 and 336 and the vertical buried oxide 316 are formed from the same etch-stop material or different etch-stop materials, all of which are substantially impervious to the process and etchant used to form the cavities 374 and 376. The lateral fences 334 and 336, and the vertical buried oxide 316 may be materials that are not etched by the etch process used to form the cavities, or that are etched sufficiently slowly that the fences constrains the lateral extent of the cavities and the vertical buried oxide defines the depth of the cavities. When the substrate 306 is silicon, the etchant may be, for example, XeF₂. The lateral fences and the vertical buried oxide 316 are an etch stop material with respect to the material of the substrate 306 and of the trap rich layer 322. They may be, for example, SiO₂, Si₃N₄, oxynitride or another etch stop material with respect to device portion 329. In some cases, the buried oxide 316 is SiO₂; and the lateral fences 334 and 336 are SiO₂ or another material.

In some cases, the substrate 306 and layer 318 are silicon, while the buried oxide layer and the lateral fences are silicon oxide, such as silicon dioxide. The cavities 374 and 376 may be formed by a FSMR frontside membrane release etch process; and the lateral fences and buried oxide are substantially impervious to the etch process. Different fence materials, buried oxide materials and etchants may be used with different substrate materials.

### Description of Methods

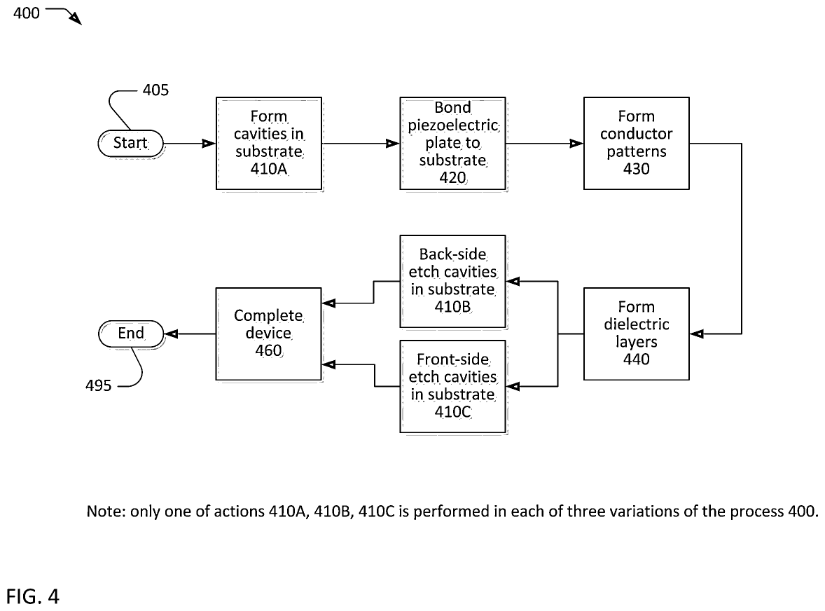

FIG. 4 is a simplified flow chart showing a process 400 for making an XBAR or a filter incorporating XBARs. The process 400 starts at 405 with a substrate and a plate of piezoelectric material and ends at 495 with a completed XBAR or filter. The completed device at 460 or 495 may be resonator device 300A. As will be described subsequently, the piezoelectric plate may be mounted on a sacrificial substrate or may be a portion of wafer of piezoelectric material. The flow chart of FIG. 4 includes only major process steps. Various conventional process steps (e.g. surface preparation, cleaning, inspection, deposition, photolithography, baking, annealing, monitoring, testing, etc.) may be performed before, between, after, and during the steps shown in FIG. 4.

The flow chart of FIG. 4 captures three variations of the process 400 for making an XBAR which differ in when and how cavities are formed in the substrate. The cavities may be formed at steps 410A, 410B, or 410C. Only one of these steps is performed in each of the three variations of the process 400.

The piezoelectric plate may be, for example, Z-cut, rotated Z-cut, or rotated Y-cut lithium niobate or lithium tantalate. The piezoelectric plate may be some other material and/or some other cut. The substrate may be silicon. The substrate may be some other material that allows formation of deep cavities by etching or other processing.

In one variation of the process 400, one or more cavities are formed in the substrate at 410A, before the piezoelectric plate is bonded to the substrate at 420. A separate cavity may be formed for each resonator in a filter device. The one or more cavities may be formed using conventional photolithographic and etching techniques. For example, the cavities may be formed using deep reactive ion etching (DRIE). Typically, the cavities formed at 410A will not penetrate through the substrate, and the resulting cavities will have a cross-section as shown in FIG. 3A.

At 420, the piezoelectric plate is bonded to the substrate. The piezoelectric plate and the substrate may be bonded by a wafer bonding process. Typically, the mating surfaces of the substrate and the piezoelectric plate are highly polished. One or more layers of intermediate materials, such as an oxide, a bonding layer or other dielectric, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers.

In a first variation of 420, the piezoelectric plate is initially mounted on a sacrificial substrate. After the piezoelectric plate and the substrate are bonded, the sacrificial substrate, and any intervening layers, are removed to expose the surface of the piezoelectric plate (the surface that previously faced the sacrificial substrate).The sacrificial substrate may be removed, for example, by material-dependent wet or dry etching or some other process.

In a second variation of 420 starts with a single-crystal piezoelectric wafer. Ions are implanted to a controlled depth beneath a surface of the piezoelectric wafer (not shown in FIG. 4). The portion of the wafer from the surface to the depth of the ion implantation is (or will become) the thin piezoelectric plate and the balance of the wafer is effectively the sacrificial substrate. After the implanted surface of the piezoelectric wafer and device substrate are bonded, the piezoelectric wafer may be split at the plane of the implanted ions (for example, using thermal shock), leaving a thin plate of piezoelectric material exposed and bonded to the substrate. The thickness of the thin plate piezoelectric material is determined by the energy (and thus depth) of the implanted ions. The process of ion implantation and subsequent separation of a thin plate is commonly referred to as “ion slicing”. The exposed surface of the thin piezoelectric plate may be polished or planarized after the piezoelectric wafer is split.

Conductor patterns and dielectric layers defining one or more XBAR devices are formed on the surface of the piezoelectric plate at 430. Typically, a filter device will have two or more conductor layers that are sequentially deposited and patterned. The conductor layers may include bonding pads, gold or solder bumps, or other means for making connection between the device and external circuitry. The conductor layers may be, for example, aluminum, an aluminum alloy, copper, a copper alloy, molybdenum, tungsten, beryllium, gold, or some other conductive metal. Optionally, one or more layers of other materials may be disposed below (i.e. between the conductor layer and the piezoelectric plate) and/or on top of the conductor layer. For example, a thin film of titanium, chrome, or other metal may be used to improve the adhesion between the conductor layers and the piezoelectric plate. The conductor layers may include bonding pads, gold or solder bumps, or other means for making connection between the device and external circuitry.

Conductor patterns may be formed at 430 by depositing the conductor layers over the surface of the piezoelectric plate and removing excess metal by etching through patterned photoresist. Alternatively, the conductor patterns may be formed at 430 using a lift-off process. Photoresist may be deposited over the piezoelectric plate and patterned to define the conductor pattern. The conductor layer may be deposited in sequence over the surface of the piezoelectric plate. The photoresist may then be removed, which removes the excess material, leaving the conductor pattern.

At 440, one or more dielectric layers may be formed by depositing one or more layers of dielectric material on the front side of the piezoelectric plate. The dielectric layers may be, for example, silicon dioxide, silicon nitride, or some other material. The dielectric layers may be deposited using conventional techniques such as sputtering or chemical vapor deposition. The one or more dielectric layers may include, for example, a dielectric layer selectively formed over the IDTs of shunt resonators to shift the resonance frequency of the shunt resonators relative to the resonance frequency of series resonators as described in U.S. Pat. No. 10,491,192. The one or more dielectric layers may include an encapsulation/passivation layer deposited over all or a substantial portion of the device

In a second variation of the process 400, one or more cavities are formed in the back side of the substrate at 410B after all the conductor patterns and dielectric layers are formed at 430. A separate cavity may be formed for each resonator in a filter device. The one or more cavities may be formed using an anisotropic or orientation-dependent dry or wet etch to open holes through the back-side of the substrate to the piezoelectric plate. In this case, the resulting resonator devices will have a cross-section as shown in FIG. 1.

In a third variation of the process 400, one or more cavities in the form of recesses in the substrate may be formed at 410C by etching the substrate using an etchant introduced through openings in the piezoelectric plate. A separate cavity may be formed for each resonator in a filter device. The one or more cavities formed at 410C will not penetrate through the substrate, and the resulting resonator devices will have a cross-section as shown in FIG. 3A.

In all variations of the process 400, the filter device is completed at 460. Actions that may occur at 460 include depositing an encapsulation/passivation layer such as silicon oxide or silicon nitride over all or a portion of the device and/or forming bonding pads or solder bumps or other means for making connection between the device and external circuitry if these steps were not performed at 430. Other actions at 460 may include excising individual devices from a wafer containing multiple devices; other packaging steps; and testing. Another action that may occur at 460 is to tune the resonant frequencies of the resonators within the device by adding or removing metal or dielectric material from the front side of the device. After the filter device is completed, the process ends at 495.

Forming the cavities at 410A may require the fewest total process steps but has the disadvantage that the XBAR diaphragms will be unsupported during all of the subsequent process steps. This may lead to damage to, or unacceptable distortion of, the diaphragms during subsequent processing.

Forming the cavities using a back-side etch at 410B requires additional handling inherent in two-sided wafer processing. Forming the cavities from the back side also greatly complicates packaging the XBAR devices since both the front side and the back side of the device must be sealed by the package.

Forming the cavities by etching from the front side at 410C does not require two-sided wafer processing and has the advantage that the XBAR diaphragms are supported during all of the preceding process steps. However, an etching process capable of forming the cavities through openings in the piezoelectric plate will necessarily be isotropic. As illustrated in FIG. 3A, such an etching process will etch laterally (i.e. parallel to the surface of the substrate) as well as etching normal to the surface of the substrate. It may be difficult to control the lateral extent and shape of cavities etched in this manner. It is desired to control such an etching process, such as using etch stops or barriers.

FIG. 5A, FIG. 5B, and FIG. 5C (collectively “FIG. 5”) are a simplified flow chart of another process 500 or method for fabricating an XBAR. The process 500 uses both lateral fences and a vertical buried oxide (for example, lateral fences 334 and vertical buried oxide 316 in FIG. 3B). Process 500 may replace process 400. Process 500 may be a frontside membrane release (FSMR) process using a hybrid fenced substrate.

To the right of each action in the flow chart is a schematic cross-sectional view representing the end of each action. The process 500 starts at step 502 in FIG. 5A and ends at step 595 in FIG. 5C with a completed resonator or filter device. The completed device at 570 or 595 may be resonator device 300B. The flow chart of FIG. 5 includes only major process steps. Various conventional process steps (e.g. surface preparation, cleaning, inspection, deposition, photolithography, baking, annealing, monitoring, testing, etc.) may be performed before, between, after, and during the steps shown in FIG. 5.

The process 500 starts at step 502 with an oxygen implant 504 into a silicon substrate 506 at and below a controlled depth D beneath a top surface of the silicon substrate 506. The depth D may be a depth for trenches that is greater than or equal to an intended maximum depth of the cavity under a diaphragm of resonators. Step 502 forms a layer in the substrate material with oxygen molecules or atoms 505 at and below depth D of the top surface. Substrate 506 may be a substrate as described for substrate 120, substrate 320 or a substrate described for FIG. 4. Substrate 506 may be a high resistivity silicon substrate. A high resistivity silicon substrate ma have a resistivity of greater than 1 k Ohm·cm. It may be silicon having resistivity of between 1000 ohm·cm and up to ˜10,000 ohm·cm.

Depth D may be the depth of a final XBAR cavity 374 that is set by energy used in the oxygen implant 504. Depth D maybe a depth of between 1 um and 100 um. In some cases, depth D is between 1 and 10 um. It may be between 2 um and 6 um. It may be between 4 um and 5 um. In some cases, depth D is between 0.2 um and 1.0 um. Sometimes it is 0.5 μm. It may be 1-3 μm. Oxygen, O+ implant conditions at step 502 can be 100-200 keV and 1.1-2.2×10¹⁸ cm⁻². These conditions can create a practical cavity depth of ˜500 nm, such as for depth D or D1.

The process 500 continues to step 510 where oxygen 505 and substrate 506 are annealed to form buried oxide layer 516 in substrate 506 at and below depth D. Annealing may form layer 516 from the implanted oxygen layer 505 and the material of the silicon substrate 506 by oxidizing material of substrate 506 with layer 505 where the layer 505 is implanted. Annealing at step 510 leaves device layer 518 of substrate 506 having thickness D above layer 516. Layer 516 is a buried oxide layer of dielectric or electrically insulating material. Layer 516 may be a buried oxide layer of SiO2.

Annealing at step 510 may be for a period of between 1.5 and 3 hours. In some cases, it may be for 2 hours. The annealing may be at a temperature of between 1100 and 1400 degrees Celsius (C) to form oxidized silicon from the implanted oxygen layer 505 and the material of the silicon substrate 506.

Layer 516 is formed at and below depth D beneath the top surface of the substrate. Layer 516 may be vertical buried oxide 316. The oxygen layer 505 and/or the buried layer 516 may have a thickness of between 0.2 um and 0.8 um. The thickness may be between 0.4 um and 0.6 um. It may be ˜500 nm.

Step 502 may be a separation by implantation of oxygen (SIMOX) technique; or may be part of a SIMOX technique that includes steps 502 and 510 to form buried oxide layer 516. This technique may implant the buried oxide layer 516 directly into the silicon wafer and form layer 516 at and below a depth D less than 1 micron.

In other cases (not shown), the buried oxide layer 516 and 316 is a vertical buried oxide horizontal ‘box’ feature formed by wafer bonding an insulator or oxide layer with similar electrical and physical characteristics to layer 516 and 316 on a top surface of substrate 506/316 where layer 516 and 316 is shown. A thickness D of a subsequent layer of the substrate material (e.g., device layer 518/318) is then bonded on top of layer 516/316. This may be a silicon on insulator (SOI) technology. This process may form an original buried Si—SiO2—Si structure through this SOI bonding process. The subsequent steps of process 500 may then occur.

In other cases (not shown), photolithography is used during oxygen implant at step 502 to define lateral extent of the oxygen layer and buried oxide layer 516 and 316. A mask may be formed over substrate 506 prior to oxygen implantation, where the mask is open as desired locations 528. In this case, the device resulting after the anneal at step 520 only has buried oxide layer 516 and 316 at or under desired locations 528. This process may be using photolithography steps during oxygen implant at step 502 to define lateral extent of the oxide layer 516 and 316.

Next, at step 520, trenches 524 and 526 are etched in a surface of the silicon substrate in the locations where the lateral fences are desired to be formed around desired locations for cavities 528. Etching at step 520 may be etching through the top surface and to depth D or D1 of the silicon substrate 506. Prior to etching, step 520 may include forming a trap rich layer 522 within or on the top surface of the substrate 506 (e.g., on top of device layer 518) to form device portion 529 having depth D1; and etching the trenches may include etching through the trap rich layer 522 and layer 518 to depth D1.

Trap rich layer 522 may be formed within the substrate, grown on the substrate and/or deposited onto the substrate using conventional processes such as thermal oxidation, evaporation, sputtering, or chemical vapor deposition. The trap rich layer 522 may be a layer formed on a surface of the substrate 506 (e.g., such as a high resistivity silicon wafer) that is immediately adjacent a bonding layer or the piezoelectric plate 342 if the bonding layer is not present. The trap-rich layer 522 has an abundance of traps that capture free carriers and reduce carrier lifetime to an extent that the conductivity of the trap-rich region approaches zero.

A trap-rich layer 522 may be formed within a silicon substrate or within device layer 518 by irradiating the surface of the substrate with neutrons, protons, or various ions (silicon, argon, nitrogen, neon, oxygen, etc.) to create defects in the crystalline structure of the substrate. Alternatively, a trap-rich region may be formed within a silicon substrate or within device layer 518 by introducing deep trap impurities such as gold, copper, or other metal ions. Such impurities may be introduced by ion implantation, diffusion, or some other method. The trap-rich region may be formed by a combination of these techniques. When the bonding layer is included, the trap-rich layer 522 may be formed before the bonding layer is formed on the substrate. Alternatively, the trap-rich layer 522 may be form by ion implantation through the bonding layer. In these cases, depth D1 is depth D.

In other cases, a trap-region layer 522 may be formed on a silicon substrate or on top of device layer 518 by depositing a layer of trap-rich material such as amorphous silicon or polysilicon (polycrystalline silicon). Here, depositing may use atomic layer deposition (ALD), physical vapor deposition (PVD) or chemical vapor deposition (CVD). When the trap-rich layer 522 is polysilicon, the average grain size of the polysilicon should be substantially smaller than the minimum spacing between adjacent electrodes or conductors formed on the surface of the piezoelectric plate 342 at a location removed from the cavities. The adjacent conductors may be signal conductors interconnecting XBARs and/or other components of a filter, such as a signal conductor and a ground conductor. In these cases, depth D1 is greater than depth D by the thickness of layer 522. In some cases, depth D and/or depth D1 is a realistic cavity depth that is pretty low, such as between 0.2 um and 1.0 um. Sometimes they are 0.5 μm. They may also be 1-3 μm.

The thickness of the trap rich region formed on or within a high resistivity silicon substrate should be greater than the thickness of an inversion layer that may form in the absence of the trap-rich layer. Trap rich layer 522 may having a thickness of between 3 nm and 400 nm over a top of the layer 518. It may have a thickness of between 5 nm and 2000 nm.

Trenches 524 and 526 are etched at locations for forming lateral fences that will bound intended locations 528 for two cavities. Etching at step 520 may include etching trenches having a width W of between 0.1 um and 10 um between the trench inside surface and a trench outside surface. Width W may be between 0.5 um and 1.5 um.

Each of trenches 524 and 526 may form a two dimensional track or perimeter for a cavity to have a volume in the substrate 506. While the trenches 524 and 526 are only shown in cross-section in FIG. 5A, it must be understood that from a top perspective, each trench is a ring, square, rectangle or other surface shape completely around the perimeter of what will become a cavity.

The trenches are etched down to and possibly partially into layer 516. Step 520 may include the trenches to the buried oxide layer 516 using the buried oxide layer as an etch stop. Etching the trenches forms trench perimeters of desired cavity locations 528 to a desired depth D1 or thickness of device portion 529. So long as the process used to etch the trenches 524 and 526 does not etch the buried layer 516, the depth D1 of the trenches is determined by the thickness of the device layer 529. When layer 522 exists, etching the trenches includes etching completely through the thickness of layer 522. Etching the trenches may be etching with XeF2.

Etching at step 520 may use a photolithography etch, or mask and etch process. The trenches 524 and 526 may be formed by etching the substrate through a suitable mask such as a photoresist mask or a hard mask. The trenches may be etched into the portion 529 using a suitable wet or dry etching process for the trap rich layer 522 and layer 518 material. etching may be done by masking, a first etch for layer 522 and a second etch for layer 518. In other cases, both layers 522 and 518 may be etched with a single etch. For example, when the substrate is silicon, the trenches may be formed using deep reactive ion etching (DRIE). Other etching processes may be used on other substrate materials.

The process 500 continues to step 530 where the trenches 524 and 526 are filled with a dielectric material to form lateral fences 534 and 536 bounding intended locations for two cavities 528. Filling the trenches may include filling the trenches in trap rich layer 522. Filling the trenches may include filling from the top of layer 516 up to at least the top of the trap rich layer 522. The lateral fences may be contiguous with the surrounding material of portion 539 outside of the locations 538.

The lateral fences 534 and 536 may be formed by filling the trenches 524 and 526 with one or more fences materials. The fences material or materials may be grown on the substrate and/or deposited onto the substrate using conventional deposition processes such as thermal oxidation, evaporation, sputtering, or chemical vapor deposition. Filling at step 530 may use atomic layer deposition (ALD), physical vapor deposition (PVD) or chemical vapor deposition (CVD).

The fences material or materials may be any materials that will function to constrain the lateral or horizontal growth of the cavity 374 when the cavity is etched in the device portion 529. The dielectric material and hence lateral fences 534 and 536 may be formed of silicon dioxide, silicon nitride, aluminum oxide, oxynitride, another etch stope or another dielectric material. When the layers 522 and 518 of device portion 529 are silicon, suitable fences materials include silicon dioxide, silicon nitride, and aluminum oxide.

The lateral fences formed at step 530 may be a single material, as shown for lateral fences 534 and 536, which may one of the previously described fences materials deposited by a conventional process such as sputtering or chemical vapor deposition. In other cases, the lateral fences may be two or more materials where a first material coats the trenches, and a second material is deposited over the first material, and so on, until the trenches are full of the deposited materials. For example, when the device portion 529 is silicon, a layer of silicon dioxide may first be grown on the top surface of the device portion 529 and the interior of the trenches. Grown oxide typically has fewer pinholes and other defects than deposited materials. Subsequently, a second material may be deposited over the grown oxide on the surface of the device portion 529 and within the trenches. There may be some benefit to depositing a material other than silicon dioxide over the grown oxide.

After the trenches are filled with one or more materials to form the lateral fences at step 530, the top surface of the substrate 506 or layer 522 may be uneven and/or covered with material used to form the fences and thus may need to be planarized. Planarization may be performed by mechanical polishing, by chemo-mechanical polishing, or some other method to form a planar top surface of portion 529, such as by exposing or creating a planar top surface of layer 522.

After step 530, locations 528 may include a volume (e.g., a volume of a sacrificial tub material) that has a length L (into the drawing page and not shown) of between 50 um and 500 um between length inside surfaces of the lateral fences, a width W1 of between 50 um and 500 um between width inside surfaces of the lateral fences, and a depth D1 of between 1 um and 100 um between a bottom surface of the plate and a top surface of the buried oxide layer 516. In some cases, width W1 is between 80-100 um wide; and length L is between 10 and 100 um long. Width W could be as small as 50 μm (e.g., on the sides of a typical resonator) to as large as 500 μm (e.g., on the top and bottom). A broader range may be from 5 μm to 7 mm. The volume of material may be etched to form the cavities.

At step 540, a piezoelectric plate 542 is bonded to the top surface of the substrate 506. Bonding at step 540 may be bonding the plate 542 to a top surface of device portion 529 or layer 522; over the fences 534 and 536; and over the desired locations for cavities 528. Techniques for bonding the piezoelectric plate were previously described for action 420 in the process 400 of FIG. 4. The description of those techniques will not be repeated.

In some cases, step 540 includes forming a bonding layer or oxide (not shown) on the planarized surface of the layer 522. The bonding layer may silicon dioxide or some material capable of bonding to the piezoelectric material (typically lithium niobate or lithium tantalate) to be used in the XBAR. The bonding layer may be formed by a conventional process such as evaporation, sputtering, chemical vapor deposition or molecular beam epitaxy. In this case, the plate is bonded to the bonding layer. The bonding layer may have thickness of between 0.5-2 um.

After step 540, the resulting hybrid fence device may be a patterned Piezo-on-Insulator substrate formed with sacrificial Silicon tubs by defining an SiO2 etch stop regions of the lateral fences 534/536 and buried oxide 516 around existing Silicon material of layer 518 and optionally of layer 522 at locations 528. Using other terms, the sacrificial tubs may be formed through a combination of vertical ‘fence’ features 534/536 formed by Si etch and SiO2 deposition and a horizontal ‘box’ feature 516, which can be formed through SIMOX or wafer bonding. The sacrificial tub is confined by SiO2 etch stop layer on all sides, allowing membrane release (e.g., FSMR)) with XeF2 or similar silicon etchant. For cavity forming approaches that only use vertical fences, those fences do not confine the cavity etch in the vertical direction, such as shown in FIG. 3A. as compared. For cavity forming that uses build up or pillar approaches, the bonding oxide (BOX) must be as thick as final cavity depth, which is undesirable for stress and thermal reasons. For most cavity forming approaches: cavity depth is limited by achievable low temperature sacrificial poly deposition thicknesses; the need of reduced membrane spacing rules (smaller die) increases poly density, which makes bonding process more difficult. The current hybrid fence approach does not increase ‘foreign surface density’ as layout changes.

At step 550, conductor patterns 552 are formed on the surface of the piezoelectric plate 542. The conductor patterns include IDT fingers 554 disposed on portions of the piezoelectric plate 542 where cavities will be formed in the substrate. The structure of and techniques for forming the conductor patterns were previously described for action 430 in the process 400 of FIG. 4. These descriptions will not be repeated.

The conductor patterns 552 include IDTs of a respective resonators and the interleaved fingers 554 of the IDTs are to be disposed on a respective diaphragm over a cavity. The piezoelectric plate and the IDTs are configured such that respective radio frequency signals applied to the one or more IDTs excite respective shear primary acoustic modes in the respective one or more diaphragms.

In some cases, at step 550, one or more dielectric layers (not shown) may be formed on the surface of the piezoelectric plate 542 over the conductor patterns 552. The dielectric layers may include a layer selectively formed over the IDT fingers of shunt resonators. The structure of and techniques for forming the dielectric layers were previously described for action 440 in the process 400 of FIG. 4. These descriptions will not be repeated.

At step 560, openings 564 and 566 are etched through the piezoelectric plate 542 and the underlying trap rich layer 522 or to device portion 539 at the desired locations for cavities 528. The openings may be circular holes or elongated slots or some other shape. As shown in FIG. 5C, the openings 564 and 566 are adjacent to the area occupied by the IDT fingers 554. In other embodiments, there may be openings within the area of the IDT fingers. In all cases, the openings are within regions encircled by the lateral fences 534 and 536.

At step 570, cavities 574 and 576 are etched into the device portion 529 at locations 528 using a liquid or gaseous etchant introduced via the openings 564 and 566, respectively. The lateral growth or width W1 of each the cavities 574 and 576 is constrained by the lateral etch-stops 534 and 536, respectively. The depth D1 of the cavities 574 and 576 is limited by the buried oxide layer 516, which functions as the vertical etch-stop. Etching the cavities releases the plate diaphragms in an FSMR process. Etching the cavities may include etching with XeF2 to release the plate diaphragms. The cavities are formed at the desired locations 528. The cavities 574 and 576 has width W1, length L (not shown but into the page) and depth D1 as noted herein. They may have other dimensions for a cavity as noted herein. The top perspective perimeter shape of the cavities may be rectangular, oval, square or another shape such as noted for the top perspective shape of the trenches or lateral fences.

Etching at 570 may be forming the cavities by removing substrate material or portion 539 from a volume bounded by the piezoelectric plate 524, the buried oxide layer 516, and the lateral fences 534 and 536 using an etchant introduced through holes 564 and 566 in the piezoelectric plate.

Etching at step 570 may use a photolithography etch, or mask and etch process. In other cases, the plate 542 and conductor pattern 552 are impervious to the etch chemistry and thus act as a de-facto mask. The cavities may be etched into the portion 529 using a suitable wet or dry etching process for the trap rich layer 522 and layer 518 material as noted for etching those layers at step 520. These descriptions will not be repeated.

If a bonding layer exists, it may or may not be removed during etching to form the cavities. If it is removed its removal may require a separate etch step and chemistry. Removal of the bonding layer may or may not remove all or part of the lateral fences and/or of the buried oxide layer 516 beneath the cavities.

The filter device is then completed at 590. Actions that may occur at 590 include depositing an encapsulation/passivation layer such as SiO₂ or Si₃O₄ over all or a portion of the device and/or forming bonding pads or solder bumps or other means for making connection between the device and external circuitry if these steps were not performed at 550. Other actions at 590 may include excising individual devices from a wafer containing multiple devices; other packaging steps; and testing. Another action that may occur at 590 is to tune the resonant frequencies of the resonators within the device by adding or removing metal or dielectric material from the front side of the device. After the filter device is completed, the process ends at 595.

The lateral fences and remaining material of device portion 539 between the cavities may form a shallow trench isolation between cavities that has a width of between 1 and 10 um; between 1 and 20 um; or between 5 and 20 um.

### Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An acoustic resonator device comprising:
a substrate having a front surface and a cavity and comprising a substrate material;
a buried oxide layer at a depth in the substrate that defines a bottom of the cavity, the buried oxide layer comprising a vertical etch-stop material different from the substrate material; and
lateral fences that defines a perimeter of the cavity, the lateral fences comprising a lateral etch-stop material different from the substrate material;
a single-crystal piezoelectric plate having opposing front and back surfaces, the back surface attached to the front surface of the substrate except for a portion of the piezoelectric plate forming a diaphragm that spans the cavity; and
an interdigital transducer (IDT) formed on the front surface of the single-crystal piezoelectric plate such that interleaved fingers of the IDT are disposed on the diaphragm.

2. The device of claim 1, wherein the buried oxide layer comprises a layer of annealed implanted oxygen and silicon substrate material.

3. The device of claim 1, wherein
the piezoelectric plate and the IDT are configured such that a radio frequency signal applied to the IDT excites a primary shear acoustic mode in the diaphragm, and
the piezoelectric plate is one of lithium niobate and lithium tantalate.

4. The device of claim 1, further comprising:
a trap rich layer disposed between and in contact with the back surface of the piezoelectric plate and the front surface of the substrate.

5. The device of claim 1, where in the substrate comprises:
a device portion having a device layer of the substrate having a first surface and a second surface, wherein the device layer second surface is the front surface of the substrate, and wherein the cavity extends from the back surface of the piezoelectric plate though the device portion to the buried oxide layer.

6. The device of claim 5, wherein
the substrate is silicon;
the device layer is silicon,
the buried oxide layer is silicon dioxide, and
the lateral fences are silicon dioxide.

7. The device of claim 1, wherein
the cavity is formed by a frontside membrane release etch process; and
the lateral fences and buried oxide are substantially impervious to the etch process.

8. A method of fabricating an acoustic resonator, comprising:
forming a buried oxide layer in a silicon substrate having opposing front and back surfaces;
forming lateral fences in the substrate at a desired location for a cavity in the substrate;
attaching a back surface of a piezoelectric plate having opposing front and back surfaces to the front surface of the substrate and over the lateral fences;
forming a conductor pattern on the front surface of the piezoelectric plate, the conductor pattern including interleaved fingers of an interdigital transducer (IDT);
forming one or more openings through the piezoelectric plate; and
etching a cavity in the substrate using an etchant introduced through the openings, wherein
a lateral extent of the cavity is defined by the lateral fences and a vertical extent of the cavity is defined by the buried oxide layer, and
after etching the cavity, a portion of the piezoelectric plate forms a diaphragm spanning the cavity and the interleaved fingers of the IDT are disposed on the diaphragm.

9. The method of claim 8, wherein forming the buried oxide layer comprises:
implanting an oxygen layer in the silicon substrate;
annealing the implanted oxygen layer and the silicon substrate to form the buried oxide layer in the silicon substrate material from the implanted oxygen layer and the silicon substrate; and
wherein the buried oxide layer is a silicon oxide.

10. The method of claim 9, wherein
the substrate is a first material capable of being etched by an etch process; and
the etch stop material is substantially impervious to the etch process.

11. The method of claim 10, wherein
the lateral fences are an etch-stop material that is one of silicon oxide, SiO2, Si3N4, oxynitride or aluminum oxide, and
the lateral fences are a material is substantially impervious to the etch process.

12. The method of claim 8, wherein
the piezoelectric plate and the IDT are configured such that a radio frequency signal applied to the IDT excites a primary shear acoustic mode in the diaphragm; and, wherein the piezoelectric plate is one of lithium niobate and lithium tantalate.

13. The method of claim 12, wherein forming the lateral fences comprises:
forming a trench in the front surface of the substrate, the trench enclosing a portion of the front surface;
filling the trench with a fence material different from a material of the substrate; and
planarizing the front surface of the substrate.

14. A method of fabricating a transversely-excited film bulk acoustic resonator (XBAR), comprising:
forming a buried oxide layer in a silicon substrate;
etching trenches in a surface of the silicon substrate and filling the trenches with a dielectric material to form lateral fences bounding an intended location for a cavity;
bonding a piezoelectric plate to the surface of the substrate; and
forming the cavity by removing substrate material from a volume bounded by the piezoelectric plate, the buried oxide layer, and the lateral fences using an etchant introduced through one or more holes in the piezoelectric plate.

15. The method of claim 14, wherein forming the buried oxide layer comprises:
implanting an oxygen layer in the silicon substrate; and
annealing the implanted oxygen layer and the silicon substrate to form the buried oxide layer in the silicon substrate material from the implanted oxygen layer and the silicon substrate.

16. The method of claim 15, wherein implanting oxygen layer in the silicon substrate comprises implanting between 1.1-2.2×10¹⁸ cm⁻² of O+ oxygen at an energy between 100 and 200 keV using a Separation by Implantation Of Oxygen (SIMOX) process; and wherein annealing the implanted oxygen layer comprises annealing the silicon substrate and implanted O+ oxygen at a temperature between 1100 and 1400 degrees Celsius (C) for a period of between 1.5 and 3 hours to form oxidized silicon from the implanted oxygen layer and the silicon substrate.

17. The method of claim 14, wherein the silicon substrate is a high resistivity silicon material; wherein the implanted oxygen layer is at a depth of between 1 um and 10 um below a top surface of the silicon substrate; wherein a thickness of the buried oxide layer is between 2 um and 8 um; and wherein the buried oxide layer is a layer of SiO2.

18. The method of claim 14, wherein etching trenches in a surface of the silicon substrate comprises etching the trenches to the buried oxide layer using the buried oxide layer as an etch stop.

19. The method of claim 14, wherein the volume has a length of between 50 um and 500 um between length inside surfaces of the lateral fences, a width of between 50 um and 500 um between width inside surfaces of the lateral fences, and a depth of between 1 um and 10 um between a bottom surface of the plate and a top surface of the buried oxide layer; wherein etching trenches comprises etching trenches having a width of between 50 μm and 500 μm between the trench inside surface and a trench outside surfaces; and wherein the volume is bounded by a bottom surface of the piezoelectric plate, a top surface of the buried oxide layer, and inside surfaces of the lateral fences.

20. The method of claim 14, further comprising forming a trap rich layer over a top of the substrate prior to etching the trenches; and wherein etching the trenches includes etching through the trap rich layer; and wherein the volume includes the trap rich layer.

21. The method of claim 14, after bonding, further comprising:
forming a conductor pattern on a front surface of the plate, the conductor pattern including one or more interdigital transducers (IDTs) of a respective one or more resonators, wherein interleaved fingers of the one or more IDTs is disposed on a respective diaphragm over a cavity, wherein the piezoelectric plate and the one or more IDTs are configured such that respective radio frequency signals applied to the one or more IDTs excite respective shear primary acoustic modes in the respective one or more diaphragms and
forming the one or more holes in the piezoelectric plate by etching through the plate at areas within the intended locations; and
wherein etching the cavities comprise etching with XeF2 to FSMR the diaphragms.
